(19) United States
(12) Patent Application Publication
(10) Pub. No.: US 2007/0018151 A1
(43) Pub. Date: Jan. 25, 2007

(54) Short-channel transistors

(76) Inventors: Henning Sirringhaus, Cambridge (GB); Jizheng Wang, Cambridge (GB)

Correspondence Address: SUGHRUE MION, PLLC, 2100 PENNSYLVANIA AVENUE, N.W., SUITE 800, WASHINGTON, DC, 20037, US

(21) Appl. No.: 10/576,246

(22) PCT Filed: Oct. 18, 2004
(86) PCT No.: PCT/GB04/04405

§ 371 Date: Sep. 27, 2006

(30) Foreign Application Priority Data
Oct. 16, 2003 (GB) 0324189.0

(51) Int. Cl. H01L 29/08

(52) U.S. Cl. 257/40

(57) ABSTRACT

An electronic switching device comprising a source electrode, a drain electrode, an insulating layer in the region between source and drain electrode, a semiconducting layer in contact with both the source and the drain electrode, and in contact with said insulating layer, wherein the smallest distance between said source and drain electrodes is less than 1 μm, and wherein the shape of the insulating layer is such that the path of smallest distance between the source-and drain electrodes intersects through a region of said insulating layer, so as to reduce the OFF current of the electronic switching device.

The present invention relates to transistors, and especially but not exclusively to transistors having short channel lengths.

Fast speed integrated circuits require patterning techniques that are capable of defining critical features down to sub-micrometer or even nanometer scale resolution. However, in conventionally designed submicrometer transistor structures, the performance of the transistor is degraded due to the increasing off-current resulted from short channel effects. For a given thickness of the gate dielectric the gate electrode gradually loses its function to turn on/off the transistor channel with decreasing channel length or increasing source-drain voltage. Techniques for reducing the short channel effect and enabling further dimension downscaling are required. Such techniques can be also beneficial in improving the performance of transistors having longer channel lengths.

According to one aspect of the present invention there is provided a thin film transistor electronic switching device, comprising: a source electrode and a drain electrode; a semiconducting region in contact with and extending between the source and drain electrodes; a gate electrode disposed for influencing the transconductance of at least part of the semiconducting region; and an insulating region located between the source and drain electrodes and configured so that the length of the shortest current path through the semiconducting region between the source and drain electrodes is greater than the shortest physical distance between the source and drain electrodes.

According to a second aspect of the present invention there is provided a method for forming a thin film transistor electronic switching device, the method comprising: forming a source electrode and a drain electrode; forming a semiconducting region in contact with and extending between the source and drain electrodes; forming a gate electrode disposed for influencing the transconductance of at least part of the semiconducting region; and forming an insulating region located between the source and drain electrodes and configured so that the length of the shortest current path through the semiconducting region between the source and drain electrodes exceeds the shortest physical distance between the source and drain electrodes.

Preferably the insulating region is configured so that the length of the shortest current path through the semiconducting region between the source and drain is greater than 1.05 times the shortest physical distance between the source and drain electrodes.

Preferably the shortest current path through the semiconducting region lies closer to the gate electrode than to all the paths of the shortest physical distance between the source and drain electrodes.

Suitably the source and drain electrodes comprise an inorganic metallic conductor or a conducting polymer.

Suitably the semiconducting region comprises any one or more of: a solution processable conjugated polymeric or oligomeric material; a material of small conjugated molecules with solubilising side chains; organic-inorganic hybrid materials self-assembled from solution and an inorganic semiconductor or nanowires.

Preferably the semiconducting region has a mobility exceeding 10³ cm²N. More preferably the semiconducting region has a mobility exceeding 20⁻³ cm²N or most preferably 50⁻³ cm²N

Suitably the semiconductor region is substantially undoped.

Suitably the source and drain electrodes make ohmic contact with the semiconductor region.

Suitably the device has a layer that comprises the source and drain electrodes and a layer that comprises the semiconductor region.

Preferably the insulating region comprises a mesa structure of a dielectric material and/or an air gap.

Suitably the device includes a gate dielectric layer between the gate electrode and the semiconducting region.

Preferably the shortest physical distance between the source and drain electrodes is less than one micrometre.

The step of forming the semiconducting region is preferably performed after the step of forming the insulating region. Alternatively the semiconducting region could be formed before the insulating region. Suitably the semiconducting region is deposited from solution in contact with the insulating region and the insulating region is capable of repelling the solution from which the semiconducting region is deposited.

Suitably the insulating region comprises a bulk portion of a first composition and a surface portion of a second composition on to which is deposited the solution from which the semiconducting region is deposited, the surface portion being capable of repelling that solution.

Preferably the thickness of the insulating region is in the range 30 to 80 nm.

Preferably the source and drain electrodes are formed by inkjet printing. Alternatively, the source and drain electrodes may be formed by a continuous film coating technique.

Suitably one or more components of the device are deposited by vacuum deposition and patterned by photolithography.

Preferably one or more components of the device are formed by electron beam lithography.

Suitably the insulating region is defined by a lithographic patterning technique or, alternatively, the insulating region is defined by embossing.

Preferably the insulating region is formed by depositing an insulating material onto the substrate, wherein the insulating material preferably deposits in the region between the source and drain electrodes, but not on top of the source-drain electrodes. Suitably the insulating material is deposited from a liquid phase or, alternatively, from a vapour phase.

According to one preferred aspect of the present invention, the off-current of short channel submicrometre transistors can be greatly suppressed by inserting an insulating mesa-like barrier in-between source and drain electrodes which is coated with the semiconducting layer. The presence of the mesa which prevents current flow along the path of shortest distance between source and drain electrodes has been found to result in lowering of transistor off currents, while in conventional structures without mesa a high off current is flowing between source and drain electrodes if the channel length is below 1 μm. The beneficial role of the insulating barrier has been observed for both inorganic metal electrodes patterned by electron beam lithography, as well as conducting polymer electrodes fabricated by inkjet printing and dewetting.

The invention will now be described by way of example with reference to the accompanying figures, which are as follows:

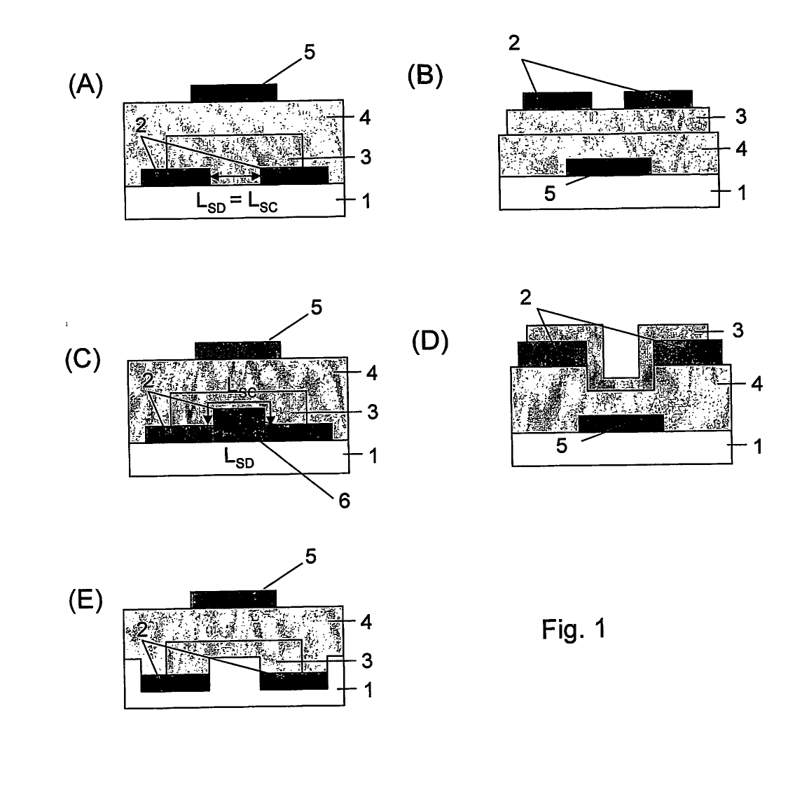

FIG. 1 shows a schematic diagram with top-gate (A) and bottom-gate (B) transistors according to the prior art, and examples of top-gate (C) and (E), as well as bottom-gate (D) transistors according to the present invention.

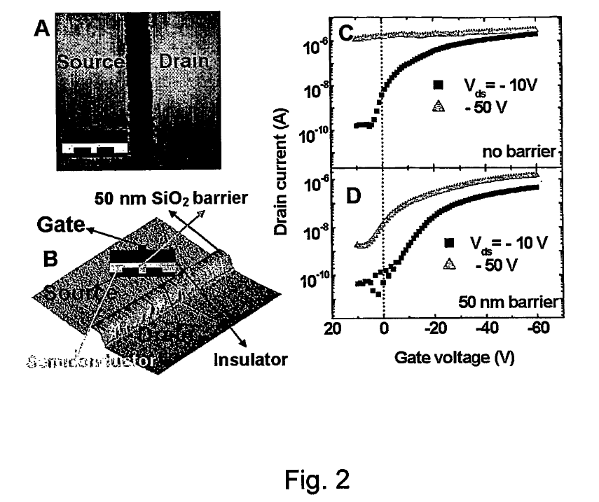

FIG. 2 shows AFM (Atomic Force Microscope) pictures of the source-drain electrodes (A) and transfer characteristics (C) of a conventional non-mesa type transistor according to FIG. 1(A), and AFM pictures of the source-drain electrodes (B) and transfer characteristics (D) of a mesa-type transistor according to FIG. 1C. The channel length of both example devices is 400 nm and the channel width is 200 μm. The mesa consists of a 50 nm high insulating layer. Electrodes were defined by electron-beam lithography.

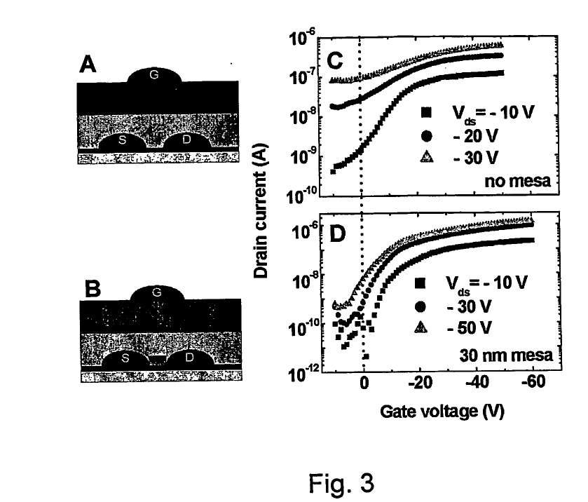

FIG. 3 shows the transfer characteristics of a conventional structure transistor (A and C) and an example mesa structure transistor (B and D) fabricated by dewetting. Channel length for both is 500 nm, width is 80 μm. Electrodes were defined by inkjet printing.

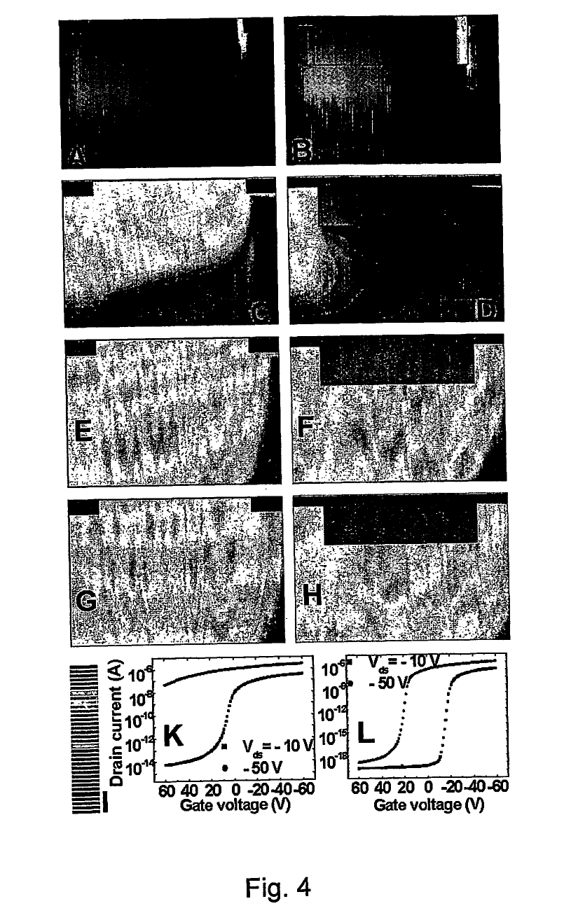

FIG. 4 shows simulation results for top gate field effect transistors with a channel length of 500 nm and channel width of 100 μm for both transistors without a mesa (A, C, E, G, K) and transistors with a 50 nm mesa (B, D, F, H, L), The gate insulating layer SiO₂ is 1 μm thick (the insulating layer and gate electrodes are not shown in these figures), and the source (left) and drain (right) electrodes are 10 nm thick. The total thicknesses of the transistors structures without a mesa and with a mesa as shown in these figures are 100 nm and 150 nm respectively (thereby the thickness of a semiconductor layer is 100 nm in transistor structures both with and without mesas). The p-type doping concentration is 5×10¹⁶ cm⁻³.

FIGS. 4(A and B). Electric field distribution in depletion mode with voltage parameters V_{ds}=−50 V and V_{gs}=60 V. The 34-shade bar (I) runs from 0 to 1.0×10⁷ Vcm¹ with a step size of 10⁷/33.

FIGS. 4(C and D). Hole distribution in depletion mode with voltage parameters V_{ds}=−50 V and V_{gs}=60 V.

FIGS. 4(E and F). Hole distribution with voltage parameters V_{ds}=−50 V and V_{gs}=0 V.

FIGS. 4(G and H). Hole distribution in accumulation mode with voltage parameters V_{ds}=−50 V and V_{gs}=−60 V. The 34-shade bar for C, D, E, F, G, H runs from 0 to 10ⁿ, where n is from 0 to 24.6 with a step size of 24.6133.

FIGS. 4(K and L). Calculated transfer characteristics of the transistors.

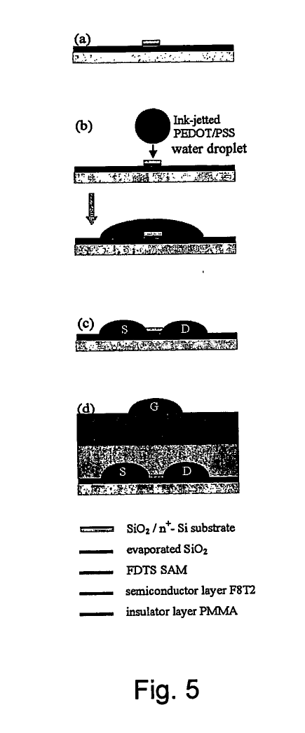

FIG. 5 shows schematic diagrams of the ink dewetting process on top of a hydrophobic mesa structure (a) FDTS SAM (Self Assembled Monolayer) is elevated by a SiO₂ mesa patterned on SiO₂/n⁺-Si substrate. (b) PEDOT/PSS water solution is ink-jetted on top of FDTS SAM. (c) PEDOT/PSS is dewetted by FDTS/SiO₂ mesa. (d) Structure of polymer transistor fabricated by dewetting.

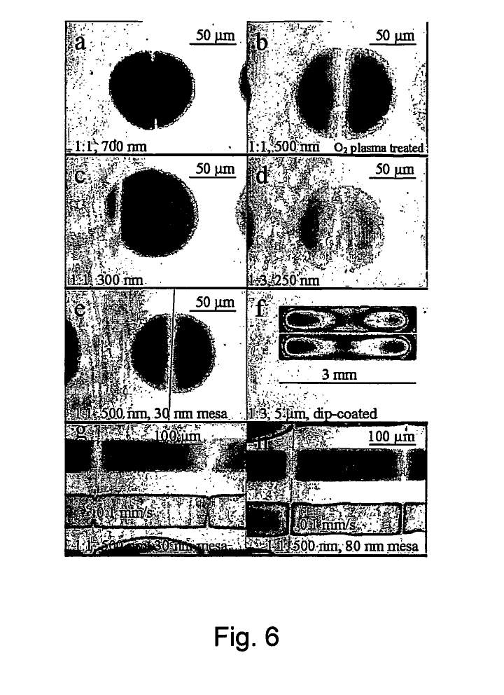

FIG. 6 shows photographs of various dewetted PEDOT/PSS illustrating factors affecting dewetting. (a) PEDOT 1:1, 700 nm FDTS SAM. (b) PEDOT 1:1, 500 nm FDTS SAM, Oxygen plasma treated surface-(c) PEDOT 1:1, 300 nm FDTS SAM. (d) PEDOT 1:3, 250 nm FDTS SAM. (e) PEDOT 1:1, 500 nm FDTS SAM, 30 nm SiO₂ mesa. (f) 5 μm FDTS SAM gap, dip coated by PEDOT 1:3. (g) PEDOT 1:1 lines printed with a jet frequency of 4 Hz, printing speed of 0.1 and 0.3 mm/s, 500 nm FDTS SAM, 30 nm mesa. (h) PEDOT 1:1 lines printed with a jet frequency of 4 Hz, printing speed of 0.1 and 0.3 mm/s, 500 nm FDTS SAM, 80 nm mesa.

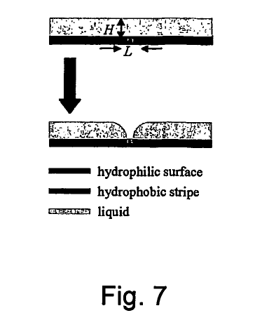

FIG. 7 Schematic diagram of dewetting model.

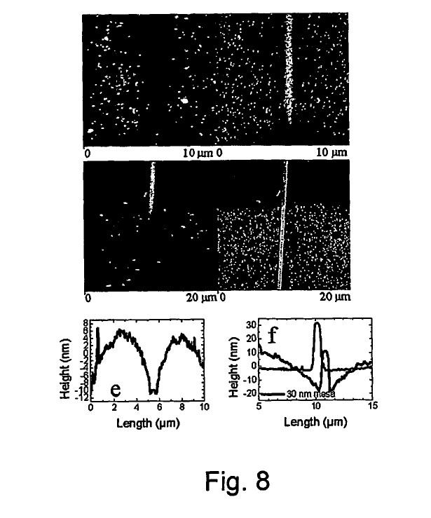

FIG. 8 AFM pictures of dewetted PEDOT/PSS. FIGS. 8a, b and FIG. 8e show AFM topography, phase and cross-sectional images, respectively, of dewetted 1:3 PEDOT/PSS droplets split on top of a 250 nm. FDTS SAM without mesa. FIGS. 8c, d and f give the corresponding dewetting results of 1:1 PEDOT/PSS droplets on a 500 nm wide FDTS SAM with 30 nm mesa.

The present invention relates to electronic switching devices and their formation.

Fast speed integrated circuits require patterning techniques that are capable of defining critical features down to sub-micrometer or even nanometer scale resolution. However, in a conventionally designed field effect transistor structure, the performance of the transistor is degraded due to the increasing off-current resulting from the short channel effect. For a given thickness of the gate dielectric the gate electrode gradually loses its function to turn on/off the transistor channel with decreasing channel length or with increasing source-drain voltage. Techniques for reducing the short channel effect and enabling further dimension downscaling are required. According to one aspect of the present invention a new architecture for a short channel field effect transistor is provided which has a off current in comparison to conventional structures.

Since the switching speed of a transistor (with a fixed gate line width) is proportional to L⁻² (L is channel length), various techniques have been developed to realize sub-micrometer channel length in order to manufacture faster integrated circuits¹⁻⁸. However, the on-off current ratio, one of the transistor's other important characteristics, decreases with decreasing channel length, resulting in degraded performance. This is a particularly important problem for thin film transistor architectures (TFT), in which the contacts to the semiconductor are made to be Ohmic, and in which the low current in the OFF state is critically dependent on the absence of any conduction paths through the bulk of the semiconducting layer. There are several causes for this loss of the ability of the gate electrode to control the source-drain current in a short-channel TFT. Hot carrier effects at high electric fields along the channel have been made reported in many inorganic, short-channel TFTS. In short-channel organic TFTs space-charge limited conduction through the bulk of the semiconducting layer has been claimed to be the source of the increased OFF current. Novel device architectures are needed to solve this problem which has prevented the use of TFT structures in applications that require submicrometer channel length to achieve higher circuit switching speeds.

Here we demonstrate that the off-current of short channel, sub-micrometer transistors can be greatly suppressed in novel device architectures which prevent the flow of leakage currents along the paths of shortest distance in the space between the source-and-drain electrodes 2 on a substrate 1 (FIG. 1), and forces the transistor current to flow through a region of the semiconductor 3 in which the charge carrier concentration and current can be effectively controlled with the gate electrode 5 spaced from the semiconducting layer by a gate dielectric 4. We define the length LSD as the length of the shortest path between a point on the edge of the source electrode in contact with the channel and a point on the edge of the drain electrode in contact with the channel. We define the length L_{SC} as the length of the shortest path between a point on the edge of the source electrode in contact with the channel and a point on the edge of the drain electrode in contact with the channel that passes entirely through the semiconducting layer. In conventional transistor architectures (FIGS. 1A, and B) the two lengths are equal.

According to one example the direct passage of current along the path of length L_{SD} may be blocked by the presence of an insulating region, such as a dielectric mesa 6 (FIGS. 1C and E) or an air gap (FIG. 1D). This results in L_{SC} being longer than L_{SD}. The current between source and drain is forced to flow along a path which lies closer to the gate electrode than the path of length L_{SD}. As shown by the electrical simulations below in this architecture, it is easier for the electrical field of the gate electrode to deplete the bulk of the semiconducting region and suppress leakage currents through the bulk of the semiconducting region in the off-state of the transistor.

The insulating region along at least a portion of the path of length L_{SD} can be fabricated in various ways. FIGS. 1C-E illustrate different examples. In the top-gate configuration of FIG. 1C an insulating mesa 6 can be defined by patterning an insulating layer in the space between the source and drain electrodes. The mesa can be fabricated by lithographic patterning, preferably during the same step in which the source-drain electrodes are defined, in order to achieve self-alignment of the source-drain electrodes with the insulating region. Alternatively, the insulating region can be defined by deposition of a dielectric material onto the substrate that has an affinity for the region between the source-drain electrode, but does not deposit on top of the source-drain electrodes themselves. This can be achieved, for example, by depositing the dielectric material from a liquid and preparing the surface of the source-drain electrode as to repel the ink of the dielectric material. Alternatively, the dielectric material can be deposited from liquid phase, and the surface of the source-drain region is prepared such that the dielectric material has a very small sticking coefficient on the surface of the source-drain electrodes.

For the bottom-gate configuration of FIG. 1D, a depression may be defined in the dielectric layer, for example by etching the dielectric layer. The etching step can be performed after the patterning of the source-drain electrodes deposited on the surface of the gate dielectric, in which case the edges of the source-drain electrodes will be aligned with the depression. The semiconducting layer may then be deposited into the depression in such a way that it conformally coats the depression, i.e. its thickness inside the depression is of similar magnitude than on top of the surface of the source-drain electrodes. Alternatively, the depression of the dielectric layer may also be achieved by embossing of the dielectric layer. The embossing step can be performed after the deposition of the source-drain electrodes, in such a way that the source-drain material adheres strongly to the embossing stamp, and the source-drain material is removed from the substrate in the region of the depression. In FIG. 1E a similar effect may be achieved for a top-gate device by depositing the source-drain electrodes into recessed structures of an insulating substrate. The source-drain electrodes can be deposited by inkjet printing, for example. The ink can be confined to the recessed structure by bringing the surface of the substrate in contact with a flat stamp comprising a surface modification agent, such as a self-assembled monolayer, which renders the surface of the substrate in the non-recessed substrate regions lipophobic to the ink, while retaining the lipophilic nature of the substrate in the recessed substrate regions. It will be apparent to a person skilled in the art that variations of such top- or bottom-gate devices configurations with either top or bottom source-drain contacts can be realized in similar ways.

We now focus on the particular embodiment of FIG. 1C in which a mesa with a thickness higher than the thickness of the source-drain electrodes is inserted between source and drain. The presence of the mesa has been found to result in lowering of the transistor OFF currents. The beneficial role of the insulating barrier has been observed for both inorganic metal electrodes patterned by electron beam lithography, as well as conducting polymer electrodes fabricated by inkjet printing and dewetting. Detailed device modeling has been performed to investigate the device physics that is responsible for the improved characteristics of the mesa-TFT structure.

AFM pictures of the source-drain transistor structures investigated here are shown in FIG. 2. One is a conventional structure (FIG. 2A), the other (FIG. 2B) is a mesa-TFT structure designed to decrease the OFF current by the insertion of an insulating mesa between source and drain electrodes. Electrodes were patterned by a lift-off process in the following way: Narrow lines were written into a 250 nm resist layer of polymethylmethacrylate (PMMA) on a SiO₂/n⁺-Si substrate by electron beam lithography (EBL). The exposure conditions were chosen such that resist after development had a wedge-shaped edge with resist thickness decreasing towards the line. The well (or line) width was controlled by varying the exposure dose. (We used a SiO₂/n⁺-Si substrate to avoid charging effects.) After the development of the exposed PMMA resist the substrate surface in the electron beam exposed regions was modified with a layer of Al deposited by vacuum evaporation. Alternatively, a 50 nm thick layer of SiO₂ was sputter deposited into the narrow wells defined by the electron beam, followed by Al deposition. Subsequently, the resist is dissolved in acetone, lifting-off the layer of Al/SiO₂ on top of the PMMA, leaving Al/SiO₂ narrow lines on the substrate. Then Cr (2 nm)/Au (10 nm) stripes were evaporated crossing the Al/SiO₂ narrow lines. After removing Al by common photo-resist developer MF 319 helped by ultrasonic agitation, the source-drain structures with and without SiO₂ mesa were obtained, and their AFM pictures are shown in FIG. 2 (both have a channel length of 400 nm). The AFM measurements suggest a well-defined mesa with some gold/Cr being present on portions of the side wall (FIG. 2B). After patterning source and drain electrodes, top-gate polymer field effect transistors (FETs) were fabricated by spin coating a 50 nm polymer semiconductor layer of poly(9,9′-dioctyl-fluorene-co-bithiophene) (F8T2) from xylene solution and 1 μm insulating layer of PMMA from n-butyl acetate solution, and inkjet printing a conducting polymer poly(3,4-ethylenedioxythiophene)/poly(4-styrenesulfonate) (PEDOT/PSS) top gate electrodes.

FIG. 2C shows the transfer characteristics of a conventional transistor and FIG. 2D shows the transfer characteristic of a TFT with mesa and gold source-drain electrodes. Both transistors have a channel length of 400 nm and width of 200 μm. It is seen that at a drain-source voltage of −10 V, both transistor exhibit a good on-off current ratio of 10⁴, although the conventional transistor has larger current at zero gate voltage and slightly higher OFF current in the depletion mode. However, for a drain-source voltage of −50 V, the gate almost loses its control of the transistor current in the conventional structure. For the transistor with mesa structure it is seen that the ON-OFF ratio remains at 10³. We note that the transistor ON current and the field-effect mobility measured in full accumulation are similar in both structures.

We have made similar observations in devices that were fabricated with inkjet-printed PEDOT/PSS source-drain electrodes (FIG. 3). These devices were fabricated by dewetting PEDOT/PSS water solution on top of sub-micrometer hydrophobic surface energy barriers defined by e-beam lithography. The fabrication process used is described in detail below. We have compared the characteristics of devices with a 30 nm thick SiO₂ mesa-shaped surface energy barrier modified by 1H, 1H, 2H, 2H-perfluorodecyltrichlorosilane (FDTS, C₁₀F₁₇H₄SiCl₃) with devices in which the surface energy barrier consists of a simple monolayer of FDTS. Devices were completed in top-gate configuration as described above.

FIGS. 3C and D show transfer characteristics of a conventional structure (with a monolayer surface energy barrier) and a mesa structure (of 30 nm thickness). Both have a channel length of 500 nm and width of 80 μm. It is clearly seen that the mesa structure offers similar improvements of TFT switching characteristics as in the case of the gold electrodes reported above.

Without wanting to be bound by theory, the origin of this beneficial increase of the on-off current ratio in a submicron transistor employing an insulating mesa is believed to related to the mesa blocking the direct conduction path between source and drain. In contrast, the current in a transistor with a conventional structure can directly flow from source to drain. Another possible factor that could be responsible for the effect of the mesa structure is the blocking by the mesa of impurities from the glass substrate to come in direct contact with the semiconducting layer. The mesa might prevent interfacial doping that occur when the semiconducting layer comes in direct contact with the substrate, that might contain ionic impurities such as sodium, that might be able to induce doping of the semiconducting material.

We have investigated the origin of the beneficial increase of the on-off current ratio in submicron transistors with an insulating mesa by detailed device modeling using the commercial software package Atlas™. Atlas is a physically-based device simulator developed by Silvaco International to predict the electrical characteristics that are associated with specified physical structures and bias conditions. This is achieved by approximating the operation of a device using a two or three dimensional grid, which consists of a number of grid points called nodes. By applying a set of differential equations, derived from Maxwells laws, to this grid, the transport of carriers through a structure can be simulated. This means that the electrical performance of a device can now be modeled in DC, AC, or transient modes of operation. Based on Maxwell's equations, Poisson's equation (1) and the carrier continuity, equation (2) can be solved in a whole transistor region to simulate device characteristics (we only show the related equations for holes here, for equations for electrons are analogous).

$${∇}^{2} ψ = - \frac{ρ}{ɛ} \qquad ( 1 )$$

ψ is the electrostatic potential, ε is the local permittivity, and ρ is the local space charge density. Employing this software, we are able to explore detailed physical information of FETs with various geometries.

$$\frac{\partial p}{\partial t} = \frac{1}{q} ∇ {\vec{J}}_{p} + {G}_{p} - {R}_{p} \qquad ( 2 )$$

p is the hole concentration, \vec{J}ₚ is hole current density, Gₚ is the generation rate for holes, Rₚ is recombination rate for holes, q is the magnitude of the charge on an hole. Drift-Diffusion Transport (3) is the conventional carrier transport model for \vec{J}ₚ.
\vec{J}ₚ=qμₚp\vec{E}ₚ+qDₚ∇p (3)

μₚ is hole mobility. p is hole concentration. \vec{E}ₚ is the effective electric field. Dₚ is the hole diffusion constant deduced from Einstein relationship. As a model for the organic semiconductor used in these experiments we have used a generic, idealized model, which assumes a constant, field- and concentration independent mobility of 0.001 cm²V⁻¹s⁻¹, and p-type doping of 5×10¹⁶ cm⁻³. Only hole transport is being considered. The dielectric has been assumed to have the properties of SiO₂. Such values of doping and mobility are chosen according to the values deduced from experimental transistor characteristics and capacitance-voltage measurements. A fixed, positive interface charge between the semiconductor and dielectric of 1×10¹² cm⁻² is used to reproduce the position of the turn-on voltage of the devices. No other interface and defect states in the band gap of the semiconductor are assumed. The source, drain and gate contacts are ohmic. No additional carrier generation and recombination are considered. To make the model as transparent as possible, the model was intentionally kept as simple as possible. It does not take into account, for example, the detailed field dependence of the mobility in the organic semiconductor, because the beneficial effect of the mesa structure is a general electrostatic effect, and does not depend on the specific assumptions made about material properties.

FIG. 4 gives the simulated results for transistors of both geometries with a channel length of 500 nm and channel width of 100 μm. The 1 μm thick SiO₂ insulating layer and gate electrode are not shown in these related figures. The source (left) and drain (right) electrodes are 10 nm thick. The thickness of the semiconductor in the channel region of the transistor is kept fixed at d=100 nm for both configurations.

The electric field variation along the channel in depletion at V_{g}=60V, V_{sd}=−50V and the distribution of the hole concentration at V_{g}=60 V, 0 V, and −60 V with a drain voltage of −50 V are shown in FIGS. 4A-B, and C-H, respectively. It is seen that a big difference exists in depletion mode between the device geometries (FIGS. 4C and D). For the mesa structure holes are much more easily depleted in comparison with the structure without a mesa. Even at V_{g}=+60 there exists a region between source-drain near the interface with the substrate which contains a high concentration of holes of x which cannot be depleted. These holes are injected from the source contact into the bulk of semiconductor and transported by space-charge limited conduction in the low-mobility semiconductor. This can account for the much lower OFF-current of the mesa-type transistors. At zero-gate voltage (FIGS. 4E and F), the hole concentration in the mesa-type transistors is lower, thereby a lower leakage current for mesa-type transistors is expected. In accumulation mode (FIG. 4G and H), the hole concentration in the mesa-type transistors is lower in the bulk of the semiconductor film, however, the current is mainly determined by the hole concentration in the thin accumulated layer underneath the SiO₂ insulator, which is quite similar in both cases. Therefore, the on-current for mesa-type transistors should be only slightly lower than that of non-mesa type transistors. These general features of the simulated transfer characteristics (FIGS. 4K and L) are in good agreement with the experimental results, although to simulate the detailed characteristics it would be clearly be required to include the material characteristics and device parameters for the specific semiconductor and dielectric used. We note that in the experimental measurements, the OFF current in full depletion (which is much higher than the simulated OFF current) is close to the detection limit of our measurement setup, and will also be affected by the detailed conditions at the semiconductor-substrate interface, which are not taken into account in the simulations. The TFT with mesa structure greatly improves the transistor performance and is responsible for the high ON-OFF current ratio in the submicron channel, in spite of the very thick gate dielectric used here. As clearly seen in the device without a mesa, a 1 μm gate dielectric does not satisfy the conventional scaling requirements, which assume that the dielectric needs to be significantly thinner than the channel length in order to retain good control over the source-drain current with the gate voltage.

We have also simulated transistors with different channel lengths, different thicknesses for insulating and semiconducting layers as well as mesa heights, different models for dielectric and semiconductor, as well as injection models, and different doping concentrations. Under all conditions the beneficial effect of the presence of a mesa was observed. The role of the mesa is more important, the shorter the channel length, the larger the drain bias, the higher the doping concentration, the larger the semiconductor thickness, and the larger the mesa height. The benefical effect of the mesa was observed not only for sub-micrometer-scale, but also for micrometer-scale channel lengths. It was also observed for higher mobility inorganic semiconductor simulations for which the leakage current was not carried by injected space charge, but by carriers induced by the background doping of the semiconductor.

At very high electric field (this is realized by decreasing channel length with fixed drain bias or increasing drain bias With channel length fixed), some other intricate physical mechanisms like impact ionization, high density current induced local heating, high electric field induced band to band tunneling and Fowler-Nordheim Tunneling begin to act: all of which dramatically increase the carrier numbers that contribute to the OFF-current and are important factors leading to device breakdown. It is seen that since the high electric field is sharply localized near the drain electrodes (FIGS. 4A and B, not only for depletion mode), the high electric field effects will firstly happen near the drain electrode. In the mesa-TFT structure the regions where the electric field is highest are located in the dielectric mesa region, and therefore, we expect that the mesa-TFT structure is less susceptible to-hot-carrier related degradation processes in materials and devices in which they would occur in a conventional TFT structure.

The novel TFT device architecture presented here is capable of achieving a low OFF current in short channel transistors with a comparatively thick dielectric layer. Transistor performance may be greatly improved by the insertion of an insulating mesa between source and drain electrodes. This structure allows the transistor to overcome some of the conventional scaling requirements for reduction of the dielectric thickness that is required to maintain good gate control of the source-drain current as the channel length decreases. The mesa structure allows for easier depletion of carrier conduction pathways through the bulk of the semiconductor than in conventional structures. We believe this mechanism to be generally applicable to both bottom and top-gate TFT devices, including both organic and inorganic semiconductor materials. It may also be applicable to certain configurations of silicon metal-oxide-semiconductor field-effect transistors.

In the following we describe in more detail the formation of the electronic switching device by the method of inkjet printing and dewetting.

In one preferred embodiment of this method, hydrophobic lines with widths varying from 250 nm to 20 μm are defined by electron beam lithography (EBL) (250 nm-1 μm) and optical lithography (2-20 μm), respectively. For EBL patterning, lines are written into a 250 nm resist layer PMMA on a SiO₂/n⁺-Si substrate. The line width may be controlled by varying the exposure dose. After the development of the exposed PMMA resist the substrate surface in the electron beam exposed regions is modified with a monolayer of 1H, 1H, 2H, 2H-perfluorodecyltrichlorosilane (FDTS, C₁₀F₁₇H₄SiCl₃) deposited from the vapor phase. Alternatively, a 30-80 nm thick layer of SiO₂ was sputter deposited into the narrow wells defined by the electron, followed by FDTS SAM deposition. In both cases, prior to the FDTS deposition the substrate surface is cleaned and conditioned by a short 2 min oxygen plasma exposure. This defines mesa-structures in which the surface energy barriers have a finite thickness. Subsequently, the resist is dissolved in acetone, lifting-off the layer of FDTS/SiO₂ on top of the PMMA and uncovering the underlying hydrophilic area of the substrate (FIG. 5a). Dewetting is then realized by ink-jetting conducting polymer poly(3,4-ethylenedioxythiophene)/poly(4-styrenesulfonate) (PEDOT/PSS) water droplets of different concentrations with a droplet volume of ˜65 μl per drop on top of the patterned surface (FIG. 5b). (A 1:1 (1:3) PEDOT/PSS ink denotes a 1:1 (1:3) mixture of Baytron P PEDOT/PSS solution from Bayer and pure water.) Droplets that land on top of the narrow FDTS modified lines split into two during the drying of the ink, so defining the source and drain electrodes of the FET (FIG. 5c). Top-gate polymer FETs may be fabricated employing dewetted PEDOT/PSS source and drain electrodes by spin coating a 50 nm polymer semiconductor layer of poly(9,9′-dioctyl-fluorene-co-bithiophene) (F8T2) from xylene solution and 1 μm insulating layer of PMMA from n-butyl acetate solution, and inkjet printing a PEDOTIPSS top gate electrode (FIG. 5d).

In the following we describe in more detail the process for dewetting which is used for the fabrication of the conducting polymer electrodes.

The application of solution-based direct printing techniques to the deposition and direct-write patterning of functional materials is providing new opportunities for the manufacturing of electronic devices, such as organic field effect transistors (FETs) for applications in low-cost, large-area electronics on flexible substrates^{9,10,11,12}. A range of direct printing techniques, such as screen printing^{9,10} or inkjet printing^{11,12} have been used. However, the ability of most direct printing techniques to define micrometer-size patterns is limited to typically 20-50 μm due to the difficulties of controlling the flow and spreading of liquid inks on surfaces. One approach to overcome these resolution limitations is to deposit the functional ink onto a substrate containing a predefined surface energy pattern that is able to steer the deposited ink droplets into place. This concept has been used successfully for patterning of source-drain electrodes of polymer FETs with channel lengths of 5 μm by inkjet printing¹². Dewetting by dip coating has also been used to pattern the active semiconducting layer in transistor fabrication^{13,14}.

However, the performance of FET devices would greatly benefit from further reduction of channel length to submicrometer dimensions. To achieve this a detailed understanding of the various factors that govern the interaction of droplets containing a solute of functional material with a patterned surface is required. Interactions between non-solute containing liquids and structured flat solid surfaces composed of hydrophilic and hydrophobic areas have been studied extensively theoretically and experimentally^{15,16,17,18,19,20,21,22}. However, no detailed investigation has been done on dewetting of solute-containing inks where the process of drying leads to an increase of ink viscosity that limits the ability of the ink to dewet from narrow hydrophobic strips.

Preferably, PEDOT/PSS inks are used on patterned SiO₂ surfaces modified with the fluorinated FDTS SAM (Various hydrophobic SAMs have been widely investigated and used for their hydrophobicity^{23,24,25,26}). Several factors have been found to be important to achieve splitting of droplets by submicrometer hydrophobic lines (FIG. 6). FIGS. 6a and b compare dewetting of a 1:1 PEDOT ink on top of substrates with different degree of hydrophilicity in the bare SiO₂ regions. On a substrate cleaned by oxygen plasma cleaning prior to deposition of the PMMA resist, dewetting from a 500 nm wide line is observed (FIG. 6b). In contrast, if the substrate is only cleaned by washing in acetone and isopropanol, resulting in a higher contact angle and smaller droplet diameter (FIG. 6a), even on a 700 nm wide line no complete dewetting is observed. This indicates that dewetting is favoured by a low contact angle in the wetting region of the substrate. Dewetting also depends on the relative position of the center of the droplet with respect to the hydrophobic barrier. If the hydrophobic line is close to the edge of the droplet, dewetting is possible even from very narrow hydrophobic lines (compare FIGS. 6a and c). Another key factor is the ink concentration and ink viscosity. Lower PEDOT/PSS concentrations enable dewetting on very narrow (250 nm) lines from which dewetting of more concentrated solutions is not possible (compare FIGS. 6a and d). Finally, the use of a mesa of finite thickness also improves the ability to dewet significantly. On top of a 30 nm thick mesa a concentrated 1:1 PEDOT/PSS solution is capable of dewetting from significantly narrower lines than on top of monolayer surface energy barriers (compare FIGS. 6e and a).

The influence of the total amount of liquid deposited by printing continuous lines of PEDOT/PSS across an array of hydrophobic FDTS stripes has been investigated. The total deposited liquid volume per unit length of the line was controlled by the speed of the sample stage, while keeping the droplet ejection frequency (4 Hz) the same. FIG. 6g shows the results of dewetting on a 30 nm FDTS/SiO₂ mesa. When the stage moves with a preferred speed of 0.3 mm/s, PEDOT/PSS solution is dewetted, whereas for a stage speed of 0.1 mm/s, complete dewetting did not occur. Note that also here thicker mesa structures promote dewetting (compare lines printed with 0.1 mm/s in FIGS. 6g and h).

The fluid dynamical processes behind these observations can be rationalized by a simple model. FIG. 7 shows a schematic diagram of the dewetting process (for simplicity, a two-dimensional model is used). The whole surface is covered by a thin liquid film of thickness H on top of a hydrophobic strip of length L. After dewetting, the liquid-vapor interface area is increased by an amount(2ΔS-L), where 2ΔS is the increase of the surface area in the hydrophilic regions due to the curved edges on both sides of the hydrophobic strip. The liquid-solid interface area decreases by L, and the solid-vapor interface area increases by L. For the total surface/interface energy after dewetting to be less than the surface/interface energy before dewetting, the following relationship must be satisfied:
(2ΔS−L)E_{LV}+(−LE_{LS})+LE_{SV}≦0 (4)

E_{LV}, E_{LS}, E_{SV} are the liquid-vapor, liquid-solid, solid-vapor interface tension respectively. Two conditions are assumed in our model: (a) The liquid volume before and after dewetting is assumed constant. (b) Gravity is neglected. Based on formula (4), complete dewetting occurs if:

$$\frac{L}{Δ S} \geq \frac{2}{1 - cos β} \\ cos β = \frac{{E}_{SV} - {E}_{LS}}{{E}_{LV}} \qquad ( 5 )$$

where β is the contact angle of the liquid on the hydrophobic surface. From formula (5), dewetting is favoured for hydrophobic surfaces with a large contact angle, such as FDTS. A simple model suggests that for a given dimension of the hydrophobic stripe, dewetting occurs if the thickness of the film is reduced below a critical thickness (ΔS decreases with decreasing H). This is consistent with detailed modeling of the equilibrium shape of liquid droplets on heterogeneous surfaces¹⁷, as well as kinetic modeling of dewetting induced by a spinodal instability¹⁸.

During the drying process, water is continuously evaporating and therefore the concentration of PEDOTIPSS is increasing: thereby the solution viscosity is increasing. If during the drying process the viscosity exceeds a critical value η_{critical} before the film reaches its critical thickness H_{critical} for dewetting, the droplet cannot split completely on top of the hydrophobic lines. This simple model provides an explanation for the experimental observations described above. Since the thickness of the droplet is decreasing from center to edge, dewetting occurs more easily when the hydrophobic line is located near the edge of the droplet. This is also the reason why under certain conditions (FIGS. 6a, g) dewetting starts from the thin edge of the droplet, but stops before reaching the thicker center of the droplet. On very hydrophilic surfaces, the more pronounced spreading of the droplet leads to a decrease of its thickness above the hydrophobic strip. Finally, for higher concentration inks, the critical viscosity is reached at larger liquid thicknesses, whereas a low concentration ink is able to dry to a thinner film before it reaches η_{critical}.

Within the model the beneficial effect of a preferred 30-80 nm thick mesa surface energy barrier on the dewetting process can also be understood. The effect of the mesa is to decrease the liquid film thickness on top of the hydrophobic stripe. When by water evaporation the liquid film thickness decreases to a value comparable to the mesa height, this reduction in effective thickness promotes the dewetting process. Therefore, a solute-containing ink starts to dewet on a mesa-shaped barrier at an earlier time during the drying process, i.e. at a lower viscosity, compared to a monolayer barrier. Dewetting is the easier to achieve, the larger the thickness of the mesa barrier (see FIGS. 6g, h).

The use of a hydrophilic mesa has another important advantage for using split conducting polymer ink droplets as source-drain electrodes of FET devices. FIGS. 8a, b and FIG. 8e show AFM topography, phase and cross-sectional images, respectively, of dewetted 1:3 PEDOT/PSS droplets split on top of a 250 nm FDTS, SAM without mesa. FIGS. 8c, d and f give the corresponding dewetting results of 1:1 PEDOT/PSS droplets on a 500 nm wide FDTS SAM with 30 nm mesa. It is seen in FIGS. 8a, b and e that the PEDOT/PSS contact line is not in contact with the edge of the FDTS line, and the distance between the contact lines of the two split halves of the PEDOT droplets is significantly larger (about 500 nm) than the width of the FDTS line (250 nm). This implies that after dewetting from the FDTS line the contact line of the liquid PEDOT droplets move away from the FDTS line, before it becomes pinned on the substrate. In contrast, in the case of the mesa structure (FIGS. 8c, d and f, the PEDOT/PSS contact line remains pinned to the edge of the mesa structure, and the thickness of the PEDOT/PSS deposit immediately next to the mesa barrier is finite. This can be clearly seen also in FIG. 8f comparing the height of the mesa in the PEDOT free regions (30 nm, red line) of the substrate with the height in the region of the split droplets (25 nm, black line). We believe that this is caused by the wetting nature of the hydrophilic side walls of the SiO₂ mesa which are not modified by FDTS causing the contact line of the drying PEDOT/PSS droplets to remain pinned, leaving channel length accurately defined by the mesa length. In the case of the mesa structure the PEDOT/PSS thickness profile in the vicinity of the surface energy barrier leads to a shorter FET channel length and smaller source-drain contact resistance than in the case of monolayer SAM barriers. The contact resistance is related to the finite conductivity of the PEDOT/PSS, and is minimized by thicker PEDOT films in the vicinity of the injecting source/drain edges. In the case of monolayer FDTS SAMs the channel length tends to be larger, contact resistance is higher, and lower solution concentration need to be used to achieve dewetting which further increases contact resistance. The use of a mesa structure for dewetting is crucial in achieving short submicrometer channel devices by surface energy assisted inkjet printing. By increasing the mesa height the thickness of PEDOT/PSS can be increased, and contact resistance can be lowered (see FIG. 6h by comparing the two PEDOT/PSS lines printed with different speed).

If the semiconducting material were to be deposited from a hydrophobic solution then the mesa, or at least its upper surface could be hydrophilic.

Since the switching speed of a transistor (with a fixed gate line width) is proportional to μ/L, transistors with sub-micrometer channel length and close mobility result in significantly higher switching speed than corresponding micrometer scale devices. Furthermore, submicrometer scale devices offer the possibility of probing the charge transport properties of polymer semiconductors on the length scale of the persistence length of the polymer chains, and the size of microcrystalline domains, which is reported to be on the order of 50 to 100 nm^{27,20,21}. At present, only a few methods have been demonstrated to achieve sub-micrometer channel length, and inorganic noble metals were employed as electrodes in these reported techniques^{30,31,32,33,34}. A few methods have been reported to pattern polymer source and drain electrodes^{35,36,37,38}, but sub-micrometer scale channel length can not be defined by these techniques. However, the method of surface energy assisted inkjet printing described herein can provide sufficient control over the flow of liquid ink droplets to define submicrometer critical features. Of course, EBL might not be the technique of choice for low-cost production of surface energy patterns, but alternative techniques such as direct laser patterning, soft lithographic stamping or embossing might be employed.

Dip coating, rather than inkjet printing, in combination with surface energy patterning can also be used for high resolution patterning of functional inks. For the process of dewetting, inkjet printing and dip-coating (or spin coating) play a similar role of simply delivering liquids to the substrate surface. The virtue of inkjet printing is its ability of putting accurate amounts of liquid to designed positions on the substrate. But in the case of dip coating or spin coating, the same effect can be realized by patterning the substrate surface into small hydrophilic areas where liquids are designed to occupy and hydrophobic areas where liquids are designed not to occupy. FIG. 6f shows a photograph of a photo-lithographically patterned SiO₂/n⁺-Si substrate dip-coated with 1:3 PEDOT/PSS solution. The substrate contains arrays of two rectangular hydrophilic areas separated along one side by a narrow 5 μm hydrophobic FDTS SAM barrier and bound on the other three sides by wide hydrophobic FDTS SAM regions. In such a dip-coating (or spin-coating) process, dewetting occurs as a two-step process. In the first step the liquid dewets onto the two hydrophobic regions while still covering the narrow channel in between. Then in a second step the liquid dewets from the narrow channel region. This process happens very much in the same way as described above, provided that the two hydrophilic regions are sufficiently small that the amount of confined liquid is comparable to the liquid deposited in the inkjet case. To facilitate dewetting, the size of the two hydrophilic surface regions is preferred to be sufficiently small, that the amount of confined liquid is small enough to be able to dewet from the narrow channel region before the solution viscosity reaches its critical value. By careful design of the size of the hydrophilic surface regions, which determines the amount of confined liquid, and adjustment of the solution concentration, the process of dip coating is capable of achieving similar resolution as the inkjet process described above.

According to one aspect of the present invention there is provided a transistor structure to decrease the off current of short channel transistors. Transistor performance is greatly improved by inserting an insulating mesa between source and drain electrodes. This provides a new device architecture to fabricate short channel transistors with good on-off current switching ratio and enhanced performance for application in faster speed integrated circuits.

The processes and devices described herein are not limited to devices fabricated with solution-processed polymers. Some or all of the conducting electrodes of the TFT and/or the interconnects in a circuit or display device may be formed from inorganic conductors, that are able to, for example, be deposited by the printing of a colloidal suspension or by electroplating onto a pre-patterned substrate. In devices where not all of the layers are deposited from solution, one or more PEDOT/PSS portions of the device may be replaced with an insoluble conductive material such as a vacuum-deposited conductor.

Preferred materials for the semiconducting layer includes any solution processible conjugated polymeric or oligomeric material that exhibits adequate field-effect mobilities exceeding 10⁻³ cm²/Vs and preferably exceeding 10⁻² cm²/Vs. Materials that may be suitable have been previously reviewed, for example in Ref. 31. Other possibilities include small conjugated molecules with solubilising side chains⁴⁰, semiconducting organic-inorganic hybrid materials self-assembled from solution⁴¹, or solution-deposited inorganic semiconductors such as CdSe nanoparticles⁴² or inorganic nanowires. Similarly conventional inorganic semiconductors such as amorphous or polycrystalline silicon may be used.

The electrodes may be coarse-patterned by techniques other than inkjet printing. Suitable techniques include soft lithographic printing⁴³, screen printing⁴⁴, and photolithographic patterning (see WO 99/10939), offset printing, flexographic printing or other graphic arts printing techniques.l Ink-jet printing is considered to be particularly suitable for large area patterning with good registration, in particular for flexible plastic substrates. In the case of surface-energy direct deposition, materials may also be deposited by continuous film coating techniques such as spin, blade or dip coating, which are then able to be self-patterned by the surface energy pattern.

Although preferably all layers and components of the device and circuit are deposited and patterned by solution processing and printing techniques, one or more components may also be deposited by vacuum deposition techniques and/or patterned by photolithographic processes.

Devices such as TFTs fabricated as described above may be part of more complex circuits or devices, in which one or more such devices can be integrated with each other and/or with other devices. Examples of applications include logic circuits and active matrix circuitry for a display or a memory device, or a user-defined gate array circuit.

The present invention is not limited to the foregoing examples. Aspects of the present invention include all novel and inventive aspects of the concepts described herein and all novel and inventive combinations of the features described herein.

The applicant hereby discloses in isolation each individual feature described herein and any combination of two or more such features, to the extent that such features or combinations are capable of being carried out based on the present specification as a whole in light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

### REFERENCES

1. Wang, J. Z., Zheng, Z. H., Li, H. W., W. T. S. & Sirringhaus, H. Nature Mater. 3, 171-176 (2004)

2. Collet, J. & Vuillaume, D., Appl. Phys. Left. 73, 2681-2683 (1998)

3. Collet, J., Tharaud, O., Chapoton, A. & Vuillaume, D., Appl. Phys. Left. 76, 1941-1943 (2000)

4. Austin, M. D. & Chou, S. Y., Appl. Phys. Left. 81, 4431-4433 (2002)

5. Zaumseil, J. et al., Appl. Phys. Left. 82, 793-795 (2003)

6. Zhang, Y. J. et al., Adv.Mater. 15, 1632-1635 (2003)

7. Calvet, L. E. et al., Appl. Phys. Left. 91, 757-759 (2002)

8. Wang, C., Sinder, John P., Tucker, J. R., Appi. Phys. Left. 74, 1174-1176 (1999)

9. F. Gamier, R. Hajlaoui, A. Yassar, P. Srivastava, Science 265, 1684 (1994)

10.Z. Bao, Y. Feng, A. Dodabalapur, V. R. Raju, A. J. Lovinger, Chem. Mater. 9, 1299 (1997)

11.Kateri E. Paul, William S. Wong, Steven E. Ready, Robert A. Street, Appi. Phys. Left. 83, 2070 (2003)

12. H. Sirringhaus, T. Kawase, R. H. Friend, T. Shimoda, M. Inbasekaran, W. Wu, E. P. Woo, Sicence 209, 2123 (2000)

13.R. Kagan, T. L. Breen, L. L. Kosbar, Appl. Phys. Left. 79, 3536 (2001)

14. Michael L. Chabinyc, William S. Wong, Alberto Salleo, Kateri E. Paul, Robert A. Street, AppI. Phys. Left. 81, 4260 (2002)

15. Hartmut Gau, Stephan Herminghaus, Peter Lenz, Reinhard Lipowsky, Science 283,46(1999)

16. Peter Lenz, Reinhard Lipowsky, Phys. Rev. Left. 80, 1920 (1998)

17. Martin Brinkmann, Reinhard Lipowsky, J. Appl. Phys. 92, 4296 (2002)

18. Kajari Kargupta, Ashutosh Sharma, J. Chem. Phys. 116, 3042 (2002)

19. C. Rascon, A. 0. Parry, J. Chem. Phys. 115, 5258 (2001)

20. Anton A. Darhuber, Sandra M. Troian, Scott M. Miller, J. AppI. Phys. 87, 7768 (2000)

21. C. Bauer, S. Dirtrich, Phys. Rev. E. 61, 1664 (2000)

22. M. Schneemilch, N. Quirke, J. R. Henderson, J. Chem. Phys. 118, 816 (2003)

23. Roya Maboudian, W. Robert Ashurst, Carlo Carraro, Sensors and Actuators 82, 219(2000)

24. Uthara Srinivasan, Michael R. Houston, Roger T. Howe, Journal of Microelectromechanical Systems, Vol. 7, 252 (1998)

25. Bong Hwan Kim et al, Journal of Microelectromechanical Systems, Vol. 10, 233 (2001)

26. A. Salleo, M. L. Chabinyc, M. S. Yang, R. A. Street, Appl. Phys. Left. 81, 4383 (2002)

27. H. Sirringhaus, R. J. Wilson, and R. H. Friend, Appl. Phys. Left. 77,406 (2000)

28. M. Grell, D. D. C. Bradley, G. Ungar, J. Hill, K. S. Whitehead, Macromolecules 32, 5810 (1999)

29. H. Sirringhaus, P. J. Brown, R. H. Friend, M. M Nielsen et al, Nature 401, 685 (1999)

30. J. Collet, D. Vuillaume, AppI. Phys. Left. 73, 2681 (1998)

31. J. Collet, 0. Tharaud, A. Chapoton, D. Vuillaume, Appl. Phys. Left. 76, 1941 (2000)

32. Michael D. Austin, Stephen Y. Chou, Appl. Phys. Lett. 81, 4431 (2002)

33. Jana Zaumseil, Takao Someya, Zhenan Bao, Yueh-Lin Loo, Raymond Cirelli, John A. Rogers, Appl. Phys. Lett. 82, 793 (2003)

34. Natalie Stutzmann, Richard H. Friend, Henning Sirringhaus, Science 299, 1881(2003)

35. G. H. Gelinck, T. C. T. Geuns, D. M. de Leeuw, Appl. Phys. Lett. 77, 1487 (2000)

36. Marcus Halik, Hagen Klauk, Ute Zschieschang, Tarik Kriem et al, Appl. Phys. Left. 81, 289 (2002)

37. F. J. Touwslager, N. P. Willard, D. M. de Leeuw, Appl. Phys. Left. 81, 4556 (2002)

38. Graciela B. Blanchet et al, AppI. Phys. Left. 82, 463 (2003)

39. H. E. Katz, J. Mater. Chem. 7, 369 (1997), or Z. Bao, Advanced Materials 12, 227 (2000)

40. J. G. Laquindanum, et al., J. Am. Chem. Soc. 120, 664 (1998)

41. C. R. Kagan, etal., Science 286,946(1999)

42. B. A. Ridley, et al., Science 286, 746 (1999)

43. J. A. Rogers et al., Appl. Phys. Left. 75, 1010 (1999)

44. Z. Bao, et al., Chem. Mat. 9,12999 (1997)

1. A thin film transistor electronic switching device, comprising:
a source electrode and a drain electrode;
a semiconducting region in contact with and extending between the source and drain electrodes;
a gate electrode disposed for influencing the transconductance of at least part of the semiconducting region; and
an insulating region located between the source and drain electrodes and configured so that the length of the shortest current path through the semiconducting region between the source and drain electrodes is greater than the shortest physical distance between the source and drain electrodes.

2. A device as claimed in claim 1, wherein the insulating region is configured so that the length of the shortest current path through the semiconducting region between the source and drain is greater than 1.05 times the shortest physical distance between the source and drain electrodes.

3. A device as claimed in claim 1, wherein the shortest current path through the semiconducting region lies closer to the gate electrode than to all paths of the shortest physical distance between the source and drain electrodes.

4. A device as claimed in claim 1, wherein the source and drain electrodes comprise an inorganic metallic conductor.

5. A device as claimed in claim 1, wherein the source and drain electrodes comprise a conducting polymer.

6. A device as claimed in claim 1, wherein the semiconducting region comprises a solution processible conjugated polymeric or oligomeric material.

7. A device as claimed in claim 1, wherein the semiconducting region comprises a material of small conjugated molecules with solubilising side chains.

8. A device as claimed in claim 1, wherein the semiconducting region comprises organic-inorganic hybrid materials self-assembled from solution.

9. A device as claimed in claim 1, wherein the semiconducting region comprises an inorganic semiconductor or nanowires.

10. A device as claimed in claim 1, wherein the semiconducting region has a mobility exceeding 10⁻³ cm²/V.

11. A device as claimed in claim 1, wherein the semiconductor region is substantially undoped.

12. A device as claimed in claim 1, wherein the source and drain electrodes make ohmic contact with the semiconductor region.

13. A device as claimed in claim 1, wherein the device has a layer that comprises the source and drain electrodes and a layer that comprises the semiconductor region.

14. A device as claimed in claim 1, wherein said insulating region comprises a mesa structure of a dielectric material.

15. A device as claimed in claim 1, wherein said insulating region comprises an air gap.

16. A device as claimed in claim 1, comprising a gate dielectric layer between the gate electrode and the semiconducting region.

17. A device as claimed in claim 1, wherein the shortest physical distance between the source and drain electrodes is less than one micrometre.

18. A method for forming a thin film transistor electronic switching device, the method comprising:
forming a source electrode and a drain electrode;
forming a semiconducting region in contact with and extending between the source and drain electrodes;
forming a gate electrode disposed for influencing the transconductance of at least part of the semiconducting region; and
forming an insulating region located between the source and drain electrodes and configured so that the length of the shortest current path through the semiconducting region between the source and drain electrodes exceeds the shortest physical distance between the source and drain electrodes.

19. A method as claimed in claim 18, wherein the step of forming the semiconducting region is performed after the step of forming the insulating region, the semiconducting region is deposited from solution in contact with the insulating region and the insulating region is capable of repelling the solution from which the semiconducting region is deposited.

20. A method as claimed in claim 19, wherein the insulating region comprises a bulk portion of a first composition and a surface portion of a second composition on to which is deposited the solution from which the semiconducting region is deposited, the surface portion being capable of repelling that solution.

21. A method as claimed in claim 18, wherein the thickness of the insulating region is in the range from 30 to 80 nm.

22. A method as claimed in claim 18, wherein the source and drain electrodes are formed by inkjet printing.

23. A method as claimed in claim 18, wherein the source and drain electrodes are formed by a continuous film coating technique.

24. A method as claimed in claim 18, wherein one or more components of the device are deposited by vacuum deposition and patterned by photolithography.

25. A method as claimed in claim 18, wherein one or more components of the device are formed by electron beam lithography.

26. A method as claimed in claim 18, wherein said insulating region is defined by a lithographic patterning technique.

27. A method as claimed in claim 18, wherein said insulating region is defined by embossing.

28. A method as claimed in claim 18, wherein said insulating region is formed by depositing an insulating material onto the substrate, wherein the insulating material preferably deposits in the region between the source and drain electrodes, but not on top of the source-drain electrodes.

29. A method as claimed in claim 28, wherein said insulating material is deposited from a liquid phase.

30. A method as claimed in claim 28, wherein said insulating material is deposited from a vapour phase.

31. (canceled)

32. (canceled)
